(19) United States
(12) Patent Application Publication
(10) Pub. No.: US 2014/0214220 A1
(43) Pub. Date: Jul. 31, 2014

(54) SYSTEMS AND METHODS TO ASSESS AND OPTIMIZE ENERGY USAGE FOR A FACILITY

(71) Applicant: EXPANERGY, LLC, Reno, NV (US)

(72) Inventors: Michel Roger Kamel, Buena Park, CA (US); Paul W. Donahue, Newport Coast, CA (US); Jeffrey Alan Dankworth, Reno, NV (US)

(73) Assignee: EXPANERGY, LLC, Reno, NV (US)

(21) Appl. No.: 14/227,950

(22) Filed: Mar. 27, 2014

Related U.S. Application Data
(63) Continuation of application No. 13/523,719, filed on Jun. 14, 2012.
(60) Provisional application No. 61/497,421, filed on Jun. 15, 2011.
(60) Provisional application No. 61/564,219, filed on Nov. 28, 2011.

(51) Int. Cl. G06Q 50/06; G01R 21/133

(52) U.S. Cl. CPC G06Q 50/06; G01R 21/133
USPC 700/291; 702/62

(57) ABSTRACT

A system for assessing energy usage reads read at least one computer-aided design (CAD) file relating to the architecture of a facility and extracts information from the CAD file for use in determining static energy characteristics corresponding to the architecture of the facility, acquires information for use in determining dynamic energy characteristics of the facility, and calculates a predicted energy usage of the facility based at least in part on the static and dynamic energy characteristics. The system further acquires data from at least one sensor configured to measure actual energy usage of the facility in real-time and calculates the actual energy usage of the facility. When the actual energy usage exceeds the predicted energy usage, the system transmits an alert to a user and determines corrective measures to reduce energy usage.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

U.S. patent application Ser. No. 13/452,618, filed Apr. 20, 2012, titled “SYSTEMS AND METHODS FOR ANALYZING ENERGY USAGE” is hereby incorporated herein by reference in its entirety to be considered a part of this specification.

### BACKGROUND

This disclosure relates generally to the areas of design, simulation, commissioning and operation of building management systems, building energy management systems and building energy simulation systems.

The challenge of meeting the increasing demand for energy and limited energy supplies is passed down in varying forms from regulators to utilities to consumers. At the end of the energy supply chain, building owners and facility energy managers are faced with increasing energy prices, more complex energy pricing structures, and dynamic energy pricing. In tandem, energy managers have an increasing selection of energy improvement measures and renewable energy sources to choose from.

Careful management of energy use within facilities can lead to reductions in operating expenses and capital expenditures. For buildings starting from the ground up, architects and designers should be aware of the energy properties of the building design, from the basic structure to the properties of the structural and interior components including the electrical, water, and heating and cooling systems, and design an energy efficient structure. Such energy awareness is no less important for existing facilities being retrofitted or commissioned.

But awareness is not enough. Once the energy properties of a facility are understood, there needs to be a simple way for building owners and facility managers to assess the performance of the facility and take corrective action when the actual energy consumption does not meet the energy design. Comparing the energy usage with a benchmark or an index are only applicable to the types of buildings included in the energy survey that generated the data and does not take into account real-time loads on the facility. Simulation software modeling of the energy consumption of a building under specific load conditions using numerical analysis, computational fluid dynamics or empirical equations can be accurate but the method is computationally intensive and requires expert use. It does not lend itself to real time and continuous assessment of a building's performance.

### SUMMARY

There is need to establish the predicted energy consumption based at least in part on the design, systems and construction materials of the building, taking into account environmental factors, such as weather and occupancy and compare that to the real-time and continuous assessment of the building performance.

Embodiments relate to a lifecycle system to operate an energy management system through the life of a facility. A design management element includes the design specifications such as energy performance, energy ratings, and energy consumption profiles, and an engineering design element includes architectural design specifications, such as computer aided drawings, systems with the facility and their associated energy features, and material specification including associated energy parameters. A computer aided modeling element renders 2D and 3D models of the building design, a computer aided simulation element simulates the building's structural, mechanical, electrical and thermal loads, and a building management construction element manages the building's construction. After construction is complete, a building commissioning element uses building performance energy metrics to compare the measured energy behavior and the energy performance metrics with predicted energy performance. Changes to energy components within the building during its life are monitored by a building management and control element, which also provides controls to energy consuming or saving components of the building, such as the HVAC system, automatic window shades, increased or decreased air flow based on occupancy level, for example. A continuous commissioning, verification and optimization element compares the building's design specifications with its real-time actual energy usage.

Other embodiments relate to metrics for real time and continuous energy assessment of a building and its systems used by the energy management system. In one embodiment, a method uses a mix of measured data and computed information to establish a performance metric that accurately reflects the trends in energy efficiency of systems. The method breaks down the efficiency of a building to that of its components, and calculates an overall building efficiency metric that is a weighted aggregation of the efficiency of the components. The resulting metric allows assessment of the building energy performance on a continuous basis and quantifies the impact of any improvement measure, operational change, system change, equipment malfunction, behavioral change, or weather phenomena on the building's energy performance and efficiency.

Certain embodiments relate to a method to calculate predicted energy usage of a facility. The method comprises reading at least one computer-aided design (CAD) file relating to the architecture of a facility, extracting information from the CAD file for use in determining energy characteristics corresponding to the architecture of the facility, and calculating a predicted energy usage of the facility based at least in part on information extracted from the CAD file.

In accordance with various embodiments, a system to assess energy performance of a facility is disclosed. The system comprises at least one processor configured to read at least one computer-aided design (CAD) file relating to the architecture of a facility, at least one processor configured to extract information from the CAD file for use in determining energy characteristics corresponding to the architecture of the facility, the information extracted from the CAD file comprising static energy data, and at least one processor configured to acquire information for use in determining energy characteristics corresponding to dynamic factors of the facility. The information corresponding to dynamic factors of the facility comprises dynamic energy data. The system further comprises at least one processor configured to calculate a predicted energy usage of the facility based at least in part on the static energy data and the dynamic energy data, at least one processor configured to acquire data from at least one sensor configured to measure actual energy usage of the facility, at least one processor configured to calculate the actual energy usage of the facility based at least in part on the data from the at least one sensor, at least one processor configured to compare the predicted energy usage and the actual energy usage, and at least one processor configured to transmit an alert to a user when the actual energy usage exceeds the predicted energy usage by a user selectable amount.

Certain other embodiments relate to a method to reduce energy usage of a facility. The method comprises locating information for use in determining energy characteristics corresponding to the architecture of the facility in a building information model for the facility. The information corresponding to the architecture of the facility comprises static energy data. The method further comprises acquiring actual energy usage data from at least one sensor configured to measure actual energy usage of the facility, and acquiring information for use in determining energy characteristics corresponding to dynamic factors of the facility. The information corresponding to dynamic factors of the facility comprises dynamic energy data. The method further comprises calculating a predicted energy usage of the facility based at least in part on the static energy data and the dynamic energy data, calculating the actual energy usage of the facility based at least in part on the actual energy usage data, comparing the predicted energy usage and the actual energy usage, and determining corrective measures to reduce energy usage when the actual energy usage exceeds the predicted energy usage by a user selectable amount.

According to a number of embodiments, the disclosure relates to a method to assess energy performance of a facility. The method comprises reading at least one computer-aided design (CAD) file relating to the architecture of a facility, and extracting information from the CAD file for use in determining energy characteristics corresponding to the architecture of the facility. The information extracted from the CAD file comprises static energy data. The method further comprises acquiring information for use in determining energy characteristics corresponding to dynamic factors of the facility. The information corresponding to dynamic factors of the facility comprises dynamic energy data. The method further comprises calculating a predicted energy usage of the facility based at least in part on the static energy data and the dynamic energy data, acquiring data from at least one sensor configured to measure actual energy usage of the facility, calculating the actual energy usage of the facility based at least in part on the data from the at least one sensor, comparing the predicted energy usage and the actual energy usage, and transmitting an alert to a user when the actual energy usage exceeds the predicted energy usage by a user selectable amount.

Certain embodiments relate to a method to assess energy usage of a facility. The method comprises electronically receiving static energy data associated with time independent information that relates to the architecture of a facility, electronically receiving dynamic energy data associated with time dependent information that relates to energy usage of the facility, electronically receiving sensor data from at least one sensor configured to measure the energy usage of the facility; and calculating, via execution of instructions by computer hardware including one or more computer processors, energy assessment and energy guidance data for the facility based at least in part on the static energy data, the dynamic energy data, and the sensor data.

In accordance with various other embodiments, a method to assess energy usage of a facility is disclosed. The method comprises electronically receiving static energy data associated with time independent information that relates to the architecture of a facility, electronically receiving dynamic energy data associated with time dependent information that relates to energy usage of the facility, electronically receiving sensor data from at least one sensor configured to measure the energy usage of the facility, and controlling, via execution of instructions by computer hardware including one or more computer processors, subsystems associated with the energy usage of the facility based at least in part on the static energy data, the dynamic energy data, and the sensor data.

Certain other embodiments relate to a method to optimize facility design and energy management. The method comprises electronically generating design-based mechanical and electrical drawings and layouts for the construction of a facility based at least in part on energy specifications, generating computer aided models of the facility based at least in part on the design-based mechanical and electrical drawings and layouts, electronically managing commissioning of the facility based at least in part on the energy specifications, the design-based mechanical and electrical drawings and layouts, and continuously managing and controlling, via execution of instructions by computer hardware including one or more computer processors, energy subsystems within the facility for energy usage based at least in part on the energy specifications, the design-based mechanical and electrical drawings and layouts, and sensor data form at least one sensor configured to measure energy usage of the facility.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 illustrates a schematic diagram of a system to assess and optimize energy usage for a facility, according to certain embodiments.

FIG. 2 illustrates an exemplary schematic diagram of an energy management system, according to certain embodiments.

FIG. 3 illustrates a block diagram for a system of integrated and continuous design, simulation, commissioning, real time management, evaluation and optimization of facilities.

FIG. 4 illustrates an exemplary schematic diagram of the energy balance of a building, according to an embodiment.

FIG. 5 illustrates an exemplary schematic diagram of the control volume around a building envelope, according to an embodiment.

FIG. 6 is a flow chart of an exemplary process to reduce energy usage of a facility, according to certain embodiments.

### DETAILED DESCRIPTION

The features of the systems and methods will now be described with reference to the drawings summarized above. Throughout the drawings, reference numbers are re-used to indicate correspondence between referenced elements. The drawings, associated descriptions, and specific implementation are provided to illustrate embodiments of the inventions and not to limit the scope of the disclosure.

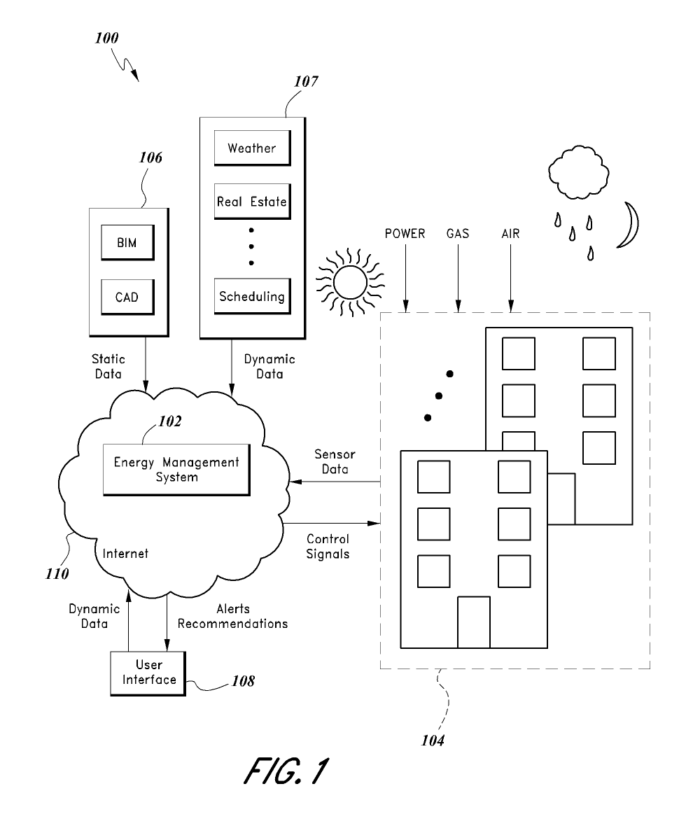

FIG. 1 illustrates an exemplary schematic diagram of a system 100 to assess and optimize energy usage for a facility or building 104. Facilities 104 can comprise one or more buildings, residences, factories, stores, commercial facilities, industrial facilities, one or more rooms, one or more offices, one or more zoned areas in a facility, one or more subsystems, such as electrical, mechanical, electromechanical, electronic, chemical, or the like, one or more floors in a building, parking structures, stadiums, theatres, or the like. The facility 104 and/or building 104 refer to the facility, its systems and its subsystems in the following discussion.

Energy entering the facility 104 can be of many forms, such as, for example, thermal, mechanical, electrical, chemical, light, and the like. The most common forms are typically electricity or power, gas, thermal mass (hot or cold air, people), and solar irradiance. The electrical energy can be generated from traditional fossil fuels, or alternate forms of power generation, such as solar cells, wind turbines, fuel cells, any type of electrical energy generator, and the like. Ambient weather conditions, such as cloudy days, or time of day, such as nighttime, may be responsible for radiant energy transfer (gains or losses).

The facility 104 comprises sensors configured to measure actual energy usage in real time. For example, sensors can measure kilowatt hours and energy spikes of electrical energy used to power the lighting system, to power the air compressor in the cooling system and to heat water for lavatories, cubic feet of gas consumed by a heating or HVAC system, amount of air flow from compressors in the cooling or HVAC system, and the like. The sensors can comprise current sensors, voltage sensors, EMF sensors, touch sensors, contact closures, capacitive sensors, trip sensors, mechanical switches, torque sensors, temperature sensors, air flow sensors, gas flow sensors, water flow sensors, water sensors, accelerometers, vibration sensors, GPS, wind sensors, sun sensors, pressure sensors, light sensors, tension-meters, microphones, humidity sensors, occupancy sensors, motion sensors, laser sensors, gas sensors (CO2, CO), speed sensors (rotational, angular), pulse counters, and the like.

The facility 104 further comprises control systems to control energy consuming and energy saving components of the facility 104. For example, one or more controllers can raise or lower automatic blinds, shut off/reduce heating or cooling in an HVAC system in the entire or just one room of the facility 104, switch usage of electricity from conventional generation to electricity generated by alternate forms, such as wind or solar, and the like.

The system 100 comprises an energy management system 102, building information modeling database 106, a dynamic information database 107, and a user interface 108. In an embodiment, the energy management system 102 is a cloud computing system based in a network 110, such as the Internet 110, as illustrated in FIG. 1. In other embodiments, the energy management system 102 is not a cloud computing system, but receives and transmits information through the network 110, such as the Internet 110, a wireless local network, or any other communication network.

The user interface 108 allows a user to transmit information to the energy management system 102 and receive information from the energy management system 102. In an embodiment, the user interface 108 comprises a Web browser and/or an application to communicate with the energy management system 102 within or through the Internet 110.

The user interface 108 can further comprise, by way of example, a personal computer, a display, a keyboard, a QWERTY keyboard, 8, 16, or more segment LEDs, LCD panels, a display, a smartphone, a mobile communication device, a microphone, a keypad, a speaker, a pointing device, user interface control elements, combinations of the same, and any other devices or systems that allow a user to provide input and receive outputs from the energy management system 102.

The building information database 106 comprises the drawings, specifications, and geographical information to build the facility 104. For example, the building information database 106 comprises design requirements, architectural drawings, such as computer aided design (CAD) drawings, system schematics, material specifications, Building Information Modeling (BIM) data, GIS (Geographic Information System) data, and the like, that are used to create the facility 104. This information or data does not change and can be considered static data.

The dynamic information database 107 comprises data from, for example, a weather database with provides weather current weather and forecast information, a real estate database which provides property valuation information, a scheduling database with provides people occupancy information for the facility 104, and other time dependent information. The dynamic information database comprises information, which unlike the static data, is capable of change. For example, the occupancy of a room within the facility 104 can change from 0 to 400 for a scheduled specific period of time. This would affect the actual and predicted energy use for the facility 104 because, there is a greater need for air conditioning to maintain the attendees comfort when the room is occupied than when it is empty. Examples of dynamic data are the ambient weather, environmental data, weather forecast, energy rates, energy surveys, grid loading, facility occupancy schedules, and the like.

The energy management system 102 receives sensor information from the facility comprising actual energy usage data for the facility 104. In addition, the energy management system 102 locates or retrieves the static data pertaining to the construction and design of the facility 104 from the building information modeling database 106. Further, the energy management system 102 receives dynamic data from the user through the user interface 108, facility 104 sensor data, the dynamic information database 107, and other dynamic data.

The energy management system 102 analyses the sensor, static, and dynamic data, and calculates a predicted energy usage of the facility 104 and an actual energy usage of the facility 104 based at least in part on the received sensor, static, and dynamic data.

In an embodiment, the energy management system 102 analyzes the data to calculate energy loads, determine possible energy reductions, identify malfunctioning systems, determine carbon footprints, calculate phase imbalance, calculate power quality, calculate power capacity, calculate energy efficiency metrics, calculate equipment duty cycles, calculate energy load profiles, identify peak energy, determine wasted energy, analyze root cause of wasted energy, identify losses due to simultaneous heating and cooling, calculate overcooling, calculate overheating, calculate schedule losses, calculate rate analysis, calculate payback of energy improvement measures, calculate occupancy efficiency, calculate optimum capacity and maximum payback of alternate energy sources, calculate demand reduction potential, calculate energy forecast, and the like.

Further, the energy management system 102 compares the predicted energy usage and the actual energy usage. In one embodiment, when the actual energy usage exceeds the predicted energy usage of the facility 104 by an amount, the energy management system 102 sends an alert to the user interface 108. In another embodiment, when the actual energy usage exceeds the predicted energy usage by the amount, the energy management system 102 sends recommendations of possible corrective measures or energy guidance data to the user interface 108. In an embodiment, energy management data or energy assessment data comprise the energy guidance data.

In a further embodiment, when the actual energy usage exceeds the predicted energy usage by the amount, the energy management system 102 transmits control signals to the control systems in the facility 104 to control the energy consuming and the energy saving components of the facility 104. For example, the control signals can generate pulse width modulation (PWM) signals to control the loading of electrical circuits, trigger relay interrupts, trigger software interrupts, generate frequency modulation signals, generate voltage modulation signals, trigger current clamping, and the like.

In one embodiment, the cloud-based energy management system 102 is an energy information system that interfaces with static data 106, dynamic data 107, an Energy Management System in facility 104, sensors in facility 104, and a user interface 108, to provide energy information, energy usage assessment and energy reduction guidance.

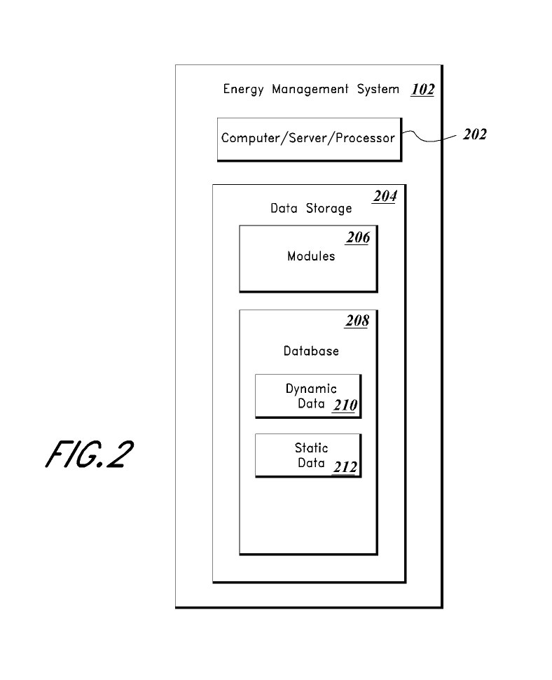

FIG. 2 illustrates an exemplary block diagram of an embodiment of the energy management system 102. The energy management system 102 comprises one or more computers 202 and memory 204. The memory 204 comprises modules 206 configured to locate system requirements and engineering design parameters, perform three-dimensional modeling, perform computer aided energy simulation, perform building construction energy modeling, perform building commissioning energy modeling, manage energy usage, and provide for the continuous commissioning, verification, and optimization for the facility 104 and its systems. The memory 204 further comprises data storage 208 including a static database 210 to store the static data and a dynamic database 212 to store the dynamic data.

In an embodiment, the energy management system 102 is remote from the facility 104 and/or the user interface 108 and communicates with the facility 104, the building information modeling database 106, and the user interface 108 through the Internet 110. The computers 202 comprise, by way of example, processors, Field Programmable Gate Arrays (FPGAs), System on a Chip (SOC), program logic, or other substrate configurations representing data and instructions, which operate as described herein. In other embodiments, the processors can comprise controller circuitry, processor circuitry, processors, general-purpose single-chip or multi-chip microprocessors, digital signal processors, embedded microprocessors, microcontrollers and the like. The memory 204 can comprise one or more logical and/or physical data storage systems for storing data and applications used by the processor 202. The memory can further comprise an interface module, such as a Graphic User Interface (GUI), or the like, to interface with the user interface 108.

### Cloud-Based Energy Management System

In the embodiment illustrated in FIG. 1, the energy management system 102 can be under control of a cloud computing environment including one or more servers and one or more data storage. The various computers/servers and data storage systems that create the “cloud” of energy management computing services comprise the computers 202 and the memory 204, respectively.

In such an embodiment, the energy management system 102 receives sensor data from sensors located in facility 104 through direct Ethernet communication with the Ethernet-enabled sensors, via an Ethernet-enabled gateway that serves as a communication interface between the energy management system 102 and sensors in facility 104, or through other communication systems.

In one embodiment, the energy management system 102 sends control signals to facility subsystems and to equipment located in facility 104 through direct Ethernet communication, or other communication protocols, or via an Ethernet-enabled gateway that serves as a communication interface between the energy management system 102 and systems in facility 104. The control signals are based at least in part on analysis of the static energy data, the dynamic energy data, and the sensor data of each facility 104.

In one embodiment, the energy management system 102 communicates with other cloud-based systems through web services to obtain dynamic data including but not limited to weather data, utility meter data, utility pricing information, security data, occupancy data, schedule data, asset data, energy surveys, solar panel output, generator output, distributed generation output, onsite power generation output, energy alerts, security alerts, emergency alerts, maintenance logs, event logs, activity logs, alert logs, environmental data, inventory data, production logs, shipping logs, attendance data, Google maps, Google Earth, and the like.

In one embodiment, the energy management system 102 obtains dynamic, static and sensor data through user interface 108.

The energy management system 102 can communicate with other systems to obtain static data including but not limited to CAD drawings associated with or relating to the architecture of the facility 104, BIM data, real estate data, Geographic Information System (GIS) data, map data, imagery data, public information data, specification fixed asset data, vendor specification sheets, operation manuals, medical data, reference manuals, and the like.

In one embodiment, the energy management system 102 communicates with users through a user interface 108. The user interface 108 can be cloud-based software, a mobile application, a desktop application, a desktop widget, a social media portal, a wall mounted device, a desk mounted device a personal device, or the like.

In one embodiment, the energy management system 102 is used to provide cloud-based managed energy services to facility 104 that may include Automated Demand Response services, energy (power, water, gas) broker services, energy equipment maintenance services, and the like.

In one embodiment, the energy management system 102 is used to provide bundled services including managed energy services, facility management services, managed security services, asset tracking services, inventory tracking services, managed personal health services, based at least in part on the static energy data, the dynamic energy data, and the sensor data of each facility.

In one embodiment, the energy management system 102 is used to deliver information to end users including marketing material, vendor information, products pricing information, equipment specification sheets, advertisement, service provider information, services pricing information, information on standards and regulations, digital publications, digital reference material, etc., based at least in part on the static energy data, the dynamic energy data, and the sensor data of each facility.

In one embodiment, the energy management system 102 is used to electronically aggregate and electronically control energy demand response and load shedding across multiple facilities based at least in part on the static energy data, the dynamic energy data, and the sensor data of each facility.

In one embodiment, information obtained from the energy management system 102 is used to execute power purchase agreements with utilities and end users for the purpose of supplying power and/or managing energy sourcing to end user.

In one embodiment, the cloud-based energy management system 102 serving a facility 104 communicates and shares best practices to another facility 104 based at least in part on the static energy data, the dynamic energy data, and the sensor data of each facility.

In one embodiment, the cloud-based energy management system 102 creates benchmarks on energy usage in facilities based at least in part on the static energy data, the dynamic energy data, and the sensor data of each facility.

In one embodiment, the cloud-based energy management system 102 has a user interface 108 that includes any or all of a web-based discussion forum, web based portal, web-based bulletin board, social media sites, twitter feeds, Really Simple Syndication (RSS) feeds, Google Maps®, Google Earth®, 3^{rd} party user interfaces, web-based blog site, web-based frequently asked questions, web-based trouble shooting guide, web-based best practices guide, and the like, that is accessible to users, facility managers, company officers, vendors, service providers, and/or the general public. Accessibility can be limited and user privileges may be in effect.

In one embodiment, the cloud-based energy management system 102 provides product performance data to vendors, manufacturers, consumer groups, marketing agencies, regulatory agencies and end users based at least in part on the static energy data, the dynamic energy data, and the sensor data of each facility.

In one embodiment, the cloud-based energy management system 102 rates energy services provided to facility based at least in part on the static energy data, the dynamic energy data, and the sensor data of each facility. The service rating information can be provided to service providers, vendors, manufacturers, consumer groups, marketing agencies, regulatory agencies, end users and others.

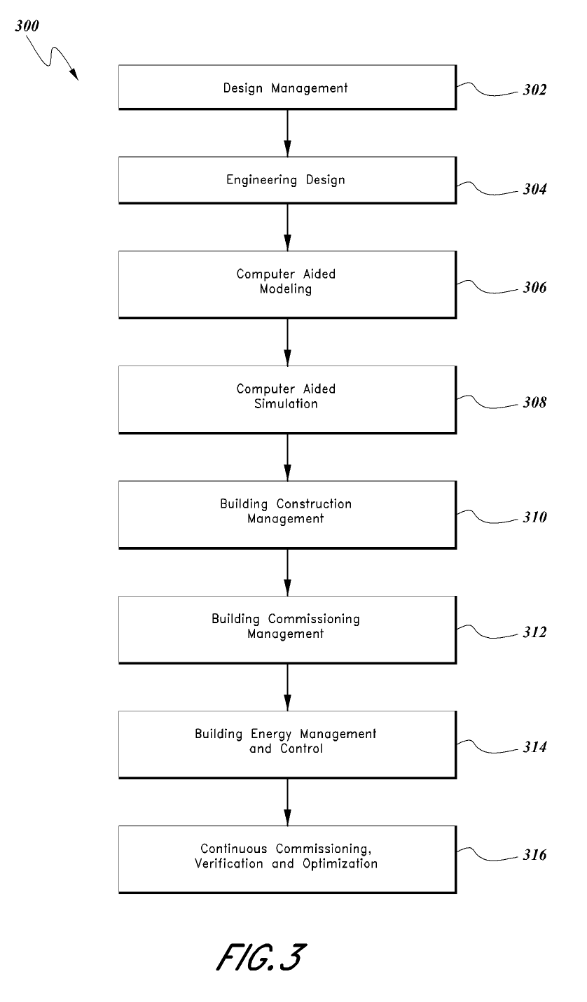

FIG. 3 illustrates a block diagram for an energy management system 300 providing integrated and continuous design, simulation, commissioning, real time management, evaluation and optimization of energy management for facilities 104. In an embodiment, the system 300 comprises a design management element 302, an engineering design element 304, a computer aided modeling element 306, a computer aided simulation element 308, a building construction management element 310, a building commissioning management element 312, a building energy management and control element 314, and a continuous commissioning, verification, and optimization element 316.

### Design Management Element

The design management element 302 provides functions for the definition and flow down of requirements for the new building 104 or for retro-commissioning the existing building 104. The requirements may include specifications for construction material, architectural design, structural design, electrical design, mechanical design, facility systems, energy performance, energy ratings, energy consumption profiles, peak demand, load profile, load factor, and specifications for the building management system. These specifications are passed on seamlessly to other elements in the system 300. The design management element 302 can be used by architects, project managers, project engineers, and owners to define and document the requirements of the new building 104 or the retro-commissioning of an existing building 104.

### Engineering Design Element

The engineering design element 304 provides functions for the structural, mechanical, and electrical engineering design of the building 104. The engineering design element 304 verifies the designs with the requirements specified in design management element 302 and alerts users of any violations or deviations in the requirements. Element 304 can be used by building architects and engineers.

Further, the engineering design element 304 can generate design-based mechanical and electrical drawings and layouts necessary for the construction or retro-commissioning of the building 104 based at least in part on the energy specifications from the design management element 302.

Further yet, the engineering design element 304 comprises a library of standard (commercially available) structural materials stored in memory 204, and permits the user to select structural components that are to be used in the design or retro-commissioning of the building 104. Examples of structural components are, but not limited to, metallic beams, wood studs, drywall, cement walls, windows, doors, floor tiles, ceiling tiles, roofing tiles, insulation, pre-defined standard wall types, ramps, stairs, elevator shafts, and the like. The library of structural components includes the design and performance attributes associated with the structural components. These attributes may include dimensions, density, mass, insulation performance, tensile and sheer strength coefficients, expansion coefficients, thermal coefficients, color, material, cost, irradiance, refractive indices, and the like. The library of structural components can be modified by the user to add new or custom structural components including their design and performance attributes. The predicted energy usage, recommendations for optimized energy performance, and the performance of corrective measures for the facility 104 can be based at least in part on the selected structural components and their associated attributes.

The engineering design element 304 further comprises a library of standard (commercially available) mechanical and electrical components/systems stored in memory 204, and permits the user to select mechanical and electrical components that are to be integrated into the design or retro-commissioning of the building 104. Examples of structural components are, but not limited to, HVAC, piping, sprinklers, lighting, pumps, elevators, escalators, shutters, generators, PV panels, and the like. The library of mechanical and electrical components/systems includes the design and performance attributes associated with the mechanical and electrical components. These attributes may include pressure ratings, energy consumption, energy generation, power quality, duty cycles, load capacity, heat emission, noise emissions, electromagnetic waves emissions, flow rates, working fluid characteristics, dimensions, density, mass, insulation performance, tensile and sheer strength coefficients, expansion coefficients, thermal coefficients, color, material, cost, irradiance, refractive indices, and the like. The library of mechanical and electrical components/systems can be modified by the user to add new or custom mechanical and electrical components including their design and performance attributes. The predicted energy usage, recommendations for optimized energy performance, and the performance of corrective measures for the facility 104 can be based at least in part on the selected mechanical and electrical components/systems and their associated attributes.

The engineering design element 304 further comprises a library of loads stored in memory 204 and permits the user to select projected or actual building mechanical, electrical and occupancy loads for the facility 104. Examples of the loads are, but not limited to, humans, plants, animals, computers, machinery, office equipment, kitchen appliances and furniture, and the like. The library of loads includes the design and performance attributes associated with the loads. These design and performance attributes may include pressure ratings, energy consumption, energy generation, power quality, duty cycles, load capacity, heat emission, noise emissions, electromagnetic waves emissions, flow rates, working fluid characteristics, dimensions, density, mass, insulation performance, tensile and sheer strength coefficients, expansion coefficients, thermal coefficients, color, material, cost, irradiance, refractive indices, and the like. The library of loads can be modified by the user or by third parties to add new components with their design and performance attributes. The predicted energy usage, recommendations for optimized energy performance, and the performance of corrective measures for the facility 104 can be based at least in part on the selected loads and their associated attributes.

In addition, the engineering design element 304 allows the user to select the geographical location of the building 104 and the building's orientation. Element 304 uses the geographical information to retrieve weather patterns, sunlight patterns, wind patterns, utility rates and schedules, and carbon footprint data associated with local energy sources. The predicted energy usage, recommendations for optimized energy performance, and the performance of corrective measures for the facility 104 can be based at least in part on the selected geographical information.

### Computer Aided Modeling Element

The computer aided modeling element 306 provides functions for the computer aided two and three dimensional geometric modeling of the building 104 and its components based at least in part on the information selected and entered in the design management element 302 and engineering design element 304.

In an embodiment, the computer aided modeling element 306 permits the user to rotate and section the geometric model of the building 104 and associated components, take a virtual tour of the building 104 and associated components, and create video clips showing the three dimensional geometric model and associated components.

Further the computer aided modeling element 306 verifies the integrity of the design and compares the design with the selected and entered in the design management element 302 and engineering design element 304 and alerts the user of any violations or conflicts in the design of the building 104 or in the layout and design of any of the associated components.

### Computer Aided Simulation Element

The computer aided simulation element 308 provides functions for the computer aided simulation of the facility's structural, mechanical, electrical and thermal loads resulting from expected environmental factors, weather patterns, projected building mechanical components and systems, projected building electrical components and systems, projected building occupancy and usage. The simulation results can include lifecycle stress analysis, lifecycle thermal analysis, lifecycle simulation of the building's energy consumption, lifecycle simulation of the building's energy costs, lifecycle simulation of the carbon footprint of the building 104, and the like.

The computer aided simulation is based at least in part on the information entered in the design management element 302 and engineering design element 304, and uses the models generated in the computer aided modeling element 306. The information is passed on to other of the elements 308, 310, 312, and 316 seamlessly without the need for additional input or human intervention.

### Building Construction Management Element

The building construction management element 310 permits the user to manage the construction process including, but not limited to, tracking construction progress, engineering modifications, component selections or modifications, budget overruns, schedule overruns, and the like.

The building construction management element 310 enables the user to view (based on access privileges) any of the information available in elements 302, 304, 306, 308, allows the user to record any modifications that are made to the initial building plans, verifies that any changes made in the construction phase do not violate the energy design requirements or the integrity of any aspect of the design or layout of the building 104, and alerts the user of any violations.

Further, the building construction management element 310 allows a construction contractor or project engineer, for example, to verify and/or select the individual equipment installed in the building 104 from an equipment library of commercially available equipment, including, but not limited to, HVAC equipment, elevators, pumps, generators, transformers, lighting systems, and the like. Further yet, the building construction management element 310 allows the construction contractor, system integrator, or project engineer, for example, to verify and/or select the sensors, such as, for example, temperature sensors, occupancy sensors, light sensors, motion sensors, gas sensors, heat sensors, water sensors, humidity sensors, air flow sensors, water flow sensors, load sensors, stress sensors, and the like, installed in the building 104 and to specify the location of the sensors.

In addition, the building construction management element 310 allows the user to enter progress information on the construction or retro-commissioning of the building 104 and the installation of equipment and allows the user to enter cost and schedule information related to the construction or retro-commissioning of the building 104.

### Building Commissioning Management Element

The building commissioning management element 312 provides functions for the commissioning of new buildings 104 or retro-commissioning of existing buildings 104 based on the design requirements and the installed systems. The building commissioning management element 312 compares the list of installed systems and construction progress to the design requirements.

Commissioning, in an embodiment, is the process of verifying, in new construction or in retro-fitting existing buildings 104, that all the subsystems for HVAC, plumbing, electrical, fire/life safety, building envelopes, interior systems, such as laboratory units, for example, cogeneration, utility plants, sustainable systems, lighting, wastewater, controls, building security, and the like achieve the owner's project requirements as intended by the building owner and as designed by the building architects and engineers.

In an embodiment, the building commissioning management element 312 comprises aspects of a building control system, a building management system, and the energy management system 102. The building control system embedded in the building commissioning management element 312 can control installed equipment that can be remotely controlled, such as, for example, security, HVAC, lighting, signage, shutters, doors, programmable logic controllers, relays, modules, controllers, current, voltage, and the like. The building management system embedded in the building commissioning management element 312 can acquire information or sensor data from sensors and sensing modules installed in the building 104.

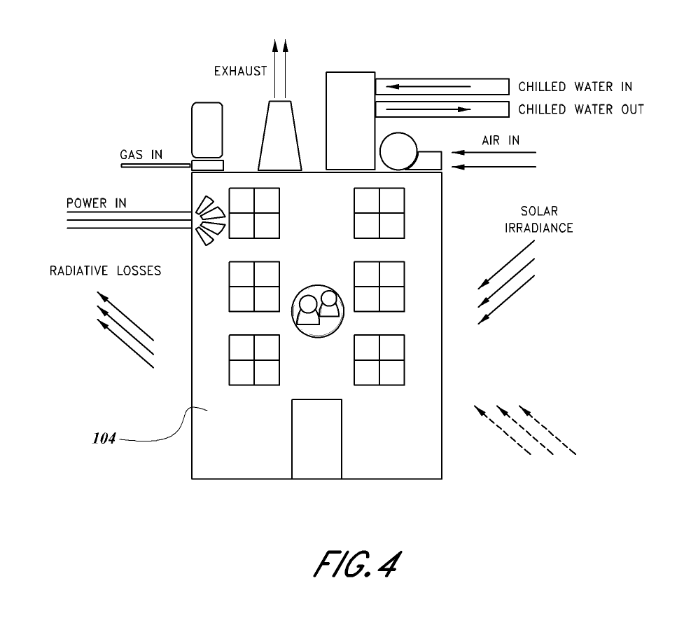

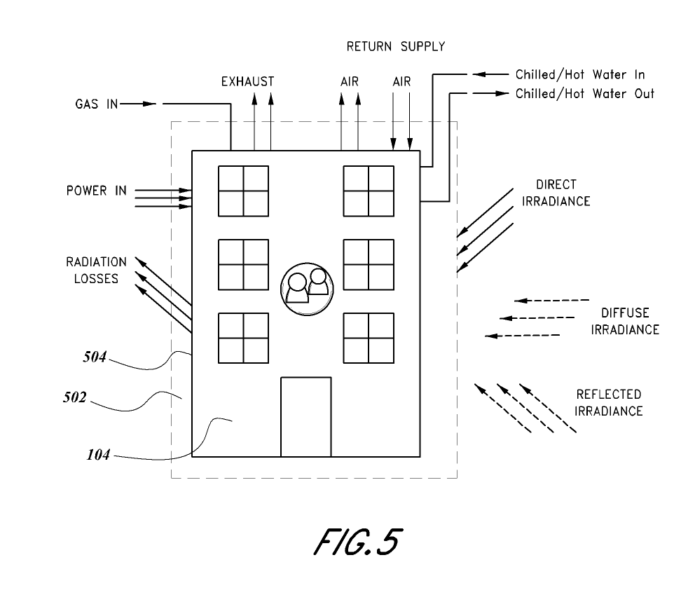

The energy management system 102 can calculate and analyze predicted and consumed power, demand, electric load profile, electric load factor for the building, panels, circuit breakers, power outlets and individual equipment, and the like, using the algorithms and information embedded or entered in one or more of the design management element 302, the engineering design element 304, the computer aided modeling element 306, the computer aided simulation element 308, and the building construction management element 310. In addition, the building commissioning management element 312 can acquire weather information and weather forecast information which can be used in the calculations for the predicted and consumed power. Examples of algorithms and metrics for calculating and analyzing predicted and consumed energy are described below in more detail with respect to FIGS. 4 and 5.

The building commissioning management element 312 initiates and cycles through control sequences simulating the energy behavior of the building 104 and its systems under different scenarios of occupancy, usage, and accidental and environmental loads, and compares measured behavior and performance metrics with the specifications and selections of the design management element 302 and engineering design element 304. Performance metrics may include energy consumption, energy generation, energy efficiency, and the like. Behavior may include specific performance and duty cycle of equipment of installed equipment, such as, for example, HVAC, generators, elevators, pumps, sprinklers, and the like.

### Building Energy Management and Control Element

The building energy management and control element 314 comprises aspects of the building management system, the building control system, and the energy management system 102, and can be used by, for example, facility managers, building owners, and the like, to manage the systems of the building 104.

The building energy management and control element 314 permits the user to record any modifications made to the building 104 or any part of the building 104, such as, for example, the addition or replacement of windows and doors, window shades or shutters, carpets, insulation, replacement of equipment, installation of new equipment, and the like. The building energy management and control element 314 permits the user to select additional equipment and sensors that are installed after the commissioning or retro-commissioning of the building 104. The items are selected from a library of equipment and sensors that are commercially available or that have been specified in any of the previous elements 310, 312, 314, 316. Element 314 allows the user to add new items to the library of equipment and sensors along with their performance specifications and attributes. Element 314 verifies the compatibility of any change or new installation with the initial requirements and specifications of the building 104, and the impact of these changes on structural, mechanical and electrical designs.

Users can enter schedule and occupancy information for the facility 104. Further, the building energy management and control element 314 manages the list of equipment and sensors entered in the other elements 302, 304, 306, 308, 310, 312 of the system 300. In an embodiment, the building energy management and control element 314 comprises a graphical user interface and provides visualization to the user of the energy calculations and corrective actions using the two and three dimensional models of the building 104 from the computer aided modeling element 306.

The building energy management and control element 314 uses the algorithms and information such as, for example, sensor data, occupancy schedule, usage schedule, ambient weather, weather forecast, utility rates, customer preferences, and the like, from the design management element 302, the engineering design element 304, the computer aided modeling element 306, the computer aided simulation element 308, the building construction management element 310, and the building commissioning management element 312 to perform various building management and control tasks. For example, the building energy management and control element 314 can perform one or more of managing the critical systems of the building 104 in real time, optimizing the management of the critical systems, identifying and prioritizing system maintenance lists, scheduling preventative maintenance of the critical systems, measuring energy consumption of the building 104, calculating the energy efficiency of the building 104, calculating the carbon footprint of the building 104, optimizing load shedding measures in real time, managing default settings for the building's critical electrical and mechanical systems and components, and the like.

The building energy management and control element 314 uses the design requirements of the design management element 302, the engineering design element 304 as well as entered geographic location information and utility rate structures to set the default settings and control algorithms for real time automated demand response and/or for intelligent demand response and verifies the effectiveness of demand response and load shedding measures implemented. Element 314 permits participation in demand response programs with algorithms for real time calculation of optimum demand response and load shedding.

In other embodiments, the building energy management and control element 314 surveys comfort levels of occupants using desktop, mobile, or web based applications and other forms of communications, solicits feedback from, for example, architects, engineers, facility managers, building managers, occupants, technicians, accountants, administrators, and others using mobile desktop or web based applications, and accepts problem reporting in real time from, for example, architects, engineers, facility managers, building managers, occupants, technicians, accountants, administrators, and others using mobile, desktop, or web based applications.

Energy usage and cost information can be transmitter, relayed, or made available to manufacturing resource planning software, material resource planning software, enterprise resource planning software, accounting software, and any other corporate, accounting or facility management software and/or database through the use of plug in modules or imbedded links in the above-referenced software.

The building energy management and control element 314 can be implemented in various architectures. In one embodiment, element 314 is implemented in a master-slave architecture using a central processor (master) and distributed sensors and actuators (slave). In another embodiment, element 314 is implemented in a client-server architecture using a central processor, such as a server, and distributed sensors and clients capable of initiating communication with the server, and responding to requests from the server. Clients can comprise one or more of actuators, controllers, processors, ICs, electrical equipment, electro-mechanical equipment with embedded processing, communication, and storage capabilities, and the like.

In a further embodiment, the building energy management and control element 314 is implemented in a peer-to-peer architecture using distributed nodes that consist of one or more of sensors, actuators, controllers, processors, ICs, electrical equipment, electro-mechanical equipment with embedded processing, communication, and storage capabilities, and the like. In yet another embodiment, element 314 is implemented in a cloud architecture using intelligence embedded in the building's electrical and electro-mechanical equipment and appliances, as is illustrated in FIG. 1.

In one embodiment, the building energy management and control element 314 is a plug-in to CAD software and building simulation and modeling software to display energy usage information using the software's 2D and 3D display functionality. Energy information can be displayed as color overlays, digital overlays, charts, gauges, or the like. In another embodiment, the building energy management and control element 314 is a plug-in to CAD software and building simulation and modeling software to control energy usage using the software's 2D and 3D display functionality. In a further embodiment, the building energy management and control element 314 is a plug-in to energy management system (EMS) and energy information systems (EIS) software to import CAD and BIM data into the EMS and EIS software.

### Continuous Commissioning, Verification and Optimization Element

The continuous commissioning, verification, and optimization element 316 provides functions for the continuous commissioning, verification and optimization of the building 104 and associated systems.

The continuous commissioning, verification, and optimization element 316 uses the algorithms and information of the design management element 302, the engineering design element 304, the computer aided modeling element 306, the computer aided simulation element 308, the building construction management element 310, the building commissioning management element 312, and the building energy management and control element 314 to perform various commissioning, verification, and optimization tasks. For example, the continuous commissioning, verification, and optimization element 316 can perform one or more of comparing or continuously comparing the building's behavior with respect to its predicted and actual energy usage with the design requirements, comparing or continuously comparing the building's behavior with respect to its predicted and actual energy usage with its behavior at the time of commissioning, continuously comparing in real time the simulated building behavior and loads, such as the structural, mechanical and electrical loads, with the measured behavior and loads, continuously calculating in real time building performance metrics, including but not limited to structural metrics, mechanical metrics, energy and energy efficiency metrics, carbon footprint metrics and the like.

Further, the continuous commissioning, verification, and optimization element 316 compares measured performance with expected and simulated performance to assess, validate and/or improve the algorithms used in the design management element 302, the engineering design element 304, the computer aided modeling element 306, the computer aided simulation element 308, the building construction management element 310, the building commissioning management element 312, and the building energy management and control element 314.

The continuous commissioning, verification, and optimization element 316 calculates in real time one or more energy efficiency metrics for a collection of buildings 104, a specific building or facility 104 and/or for critical equipment inside the facility 104. The energy efficiency metrics use real time measured energy information, occupancy information, usage information, equipment loads, weather information, weather forecast, thermal loads, the simulated or predicted energy information, calculated energy information, in addition to sensor data/information such as temperature, flow, pressure, occupancy, humidity, light, gas, and the like, from sensors distributed throughout the building 104 to determine the real time energy efficiency metric for the campus, building, floor, work space, equipment or any combination of the above associated with the facility 104. A time averaged efficiency rating can be calculated using the real time data for any period of time. Multiple energy efficiency metrics are defined to measure absolute energy efficiency (based on theoretical maximum efficiency for systems), relative energy efficiency (relative to rated efficiency of systems), actual energy efficiency (measured efficiency of systems), carbon footprint efficiency (overall carbon footprint efficiency for multiple energy sources used), energy cost efficiency (overall cost efficiency for multiple energy sources used), energy source and load matching efficiency (effectiveness of energy source and associated load), and the like. In an embodiment, energy management data or energy assessment data comprise at least one of the energy efficiency metrics.

In one embodiment, the continuous communication, verification and optimization element 316 is a plug-in to CAD software and building simulation and modeling software to display energy usage information using the software's 2D and 3D display functionality. Energy information can be displayed as color overlays, digital overlays, charts, gauges, or other. In another embodiment, the continuous communication, verification and optimization element 316 is a plug-in to CAD software and building simulation and modeling software to control energy usage using the software's 2D and 3D display functionality. In a further embodiment, the continuous communication, verification and optimization element 316 is a plug-in to EMS and EIS software to import CAD and BIM data into the EMS and EIS software.

In one embodiment, one or more of the design management element 302, the engineering design element 304, the computer aided modeling element 306, the computer aided simulation element 308, the building construction management element 310, the building commissioning management element 312, the building management and control element 314, and the continuous communication, verification and optimization element 316 are part of the integrated software that is used at one or more stages of a building's life cycle starting from design through operations and de-commissioning. In this embodiment, the integrated software comprises the facility's Energy Management System 102.

### Energy Metrics

A method enables real time and continuous energy assessment of the building 104 and its systems. The method uses a mix of measured data and computed information to establish a performance metric that accurately reflects the trends in energy efficiency of systems. The method breaks down the efficiency of the building 104 to that of its components and the energy management system 102 calculates an overall building efficiency metric that is a weighted aggregation of the efficiency of the components.

The energy consumption of the building 104 is a function of several factors, including, but not limited to:
Ambient weather conditions
Building location and orientation
Building envelope design, material and construction
HVAC design and components
Lighting design and components
Building activity mix
Occupancy levels and schedules
Equipment load

Most of the above factors are dynamic in nature and therefore the energy performance of the building 104 will be a function of time. An accurate performance metric will have to take into account the above factors in real time.

FIG. 4 illustrates an exemplary schematic diagram of the energy balance of the building 104. The change in the internal energy of a closed system is equal to the amount of heat supplied to the system minus the amount of work performed by the system on its surroundings. The building 104 is continuously exchanging energy with its surroundings. The energy entering the building 104 can be of many forms, such as, for example, thermal, mechanical, electrical, chemical, and light. The most common forms of energy entering a building are electric, radiant energy (solar light, body heat), thermal energy (through the walls, air flow, water flow), and chemical energy (gas lines). Most of the energy entering the building 104 ends up in the form of thermal energy, i.e. is converted to heat. This is true for sun rays through a window, rays emitted from light bulbs, active electric power consumed by electronic devices, active electric power used to drive conveyor belts and motors, gas being burned to heat water used in HVAC systems, and the like.

As more energy is turned into heat inside the building 104, excess heat has to be removed to maintain comfortable temperatures inside the building 104. Removal of heat itself is a process that may require energy.

The main paths for heat transfer to and from the building 104 can be divided into four categories:
1. Heat conducted through surfaces, either walls or windows. This is a function of the surface's material properties of the surface, the internal surface temperature and the external surface temperature. For a given external and internal surface temperature, the heat conducted through the surface is a function of the insulation characteristics of the building envelope.

Q_{conducted}=Q_{direct radiation}+Q_{diffuse radiation}+Q_{reflected radiation}+Q_{convected}=kA(T_{surface}_{ₒᵤₜ}−T_{surface}_{ᵢₙ})
where k is the thermal conductivity of the surface, and A is the area of the surface. The thermal conductivity of a wall is a function of the wall's material and construction. It may vary from one wall to the other and sometimes within the same wall surface.
2. Heat transmitted through surfaces. This is heat entering or leaving the building in the form of transmitted radiation (light) through windows and open surfaces (open doors, open windows). It is a function of the surface transmissivity characteristics of the building envelope.
3. Heat transported by mass transfer in and out of building. This is the heat entering or leaving a building through mass transfer (air or water). The net heat added (removed) is the difference in enthalpy of the mass leaving minus that of the mass entering the building. This mass can be intentionally transferred (e.g. by HVAC systems) or unintentionally through leaks in the building envelope.
4. Heat generated in a building from other forms of energy. This is heat generated from lighting systems, plug load, or occupants.

### Measures of a Building's Energy Efficiency

The efficiency of the building 104 is defined here as a measure of how close the actual energy consumed in the building 104 is to the least amount of energy required for proper operations. The energy consumed in the building 104 is either used to run processes inside the building 104, to illuminate the building 104 or to ventilate and condition the air in the building 104. Hence, when discussing energy efficiency of the building 104, a further distinction has to be made as to whether the efficiency applies to the processes inside the building 104, the illumination of the building 104, or the ventilation and conditioning of the air inside the building 104.

$$Building Energy Efficiency \text{:}$$

$$\begin{matrix}{η}_{building} = \frac{( \begin{matrix}minimum energy needed by \\ building for proper operations\end{matrix} )}{( actual energy consumed )} \\ = \frac{{( {E}_{HVAC} + {E}_{Lighting} + {E}_{PlugLoad} )}_{minimum}}{{( {E}_{HVAC} + {E}_{Lighing} + {E}_{PlugLoad} )}_{actual}}\end{matrix}$$

In the equation above, the actual energy consumed by the building 104 can be measured. However, the minimum energy required by the building 104 is more challenging to calculate and is harder to define. The definition of the minimum energy required for the building 104 will be a function of what standards are being applied for ventilation, cooling comfort levels, and on the activities and processes occurring inside the building 104.

Individual building system efficiency can be similarly defined as such:

$$HVAC Energy Efficiency \text{:} {η}_{HVAC} = \frac{{( {E}_{HVAC} )}_{min}}{{( {E}_{HVAC} )}_{actual}}$$

$$Lighting Energy Efficiency \text{:} {η}_{Lighting} = \frac{{( {E}_{lighting} )}_{min}}{{( {E}_{lighting} )}_{actual}}$$

$$Plug Load Energy Efficiency \text{:} {η}_{PlugLoad} = \frac{{( {E}_{PlugLoad} )}_{min}}{{( {E}_{PlugLoad} )}_{actual}}$$

Again, actual energy consumed by each system can be measured directly, with the challenge limited to defining and calculating the minimum energy required for each system for proper operation.

### Building Envelope Efficiency

The building envelope efficiency, a new metric introduced here, reflects the efficiency of the building design, material and construction in maintaining the building's inside environment. It reflects how well the building is insulated from ambient conditions, irrespective of the efficiency of the HVAC system used to cool the building 104 or the energy consumed by equipment and processes inside the building 104. For example, if two buildings exist with identical geometry, location, orientation, HVAC systems, lighting systems, processes and occupancy, then they should have identical energy consumption. If equivalent systems in both buildings have the same energy efficiency, then any differences in building energy consumption is attributed to differences in envelope material and construction, with one building doing a better or worse job than the other in keeping the heat in the winter or losing it more easily in the summer. For such a case, the efficiency of the building envelope will be different. In real life, no two buildings are identical in this manner; however, this example illustrates the need for an envelope efficiency that is independent of the efficiency of the HVAC.

FIG. 5 illustrates an exemplary schematic diagram of a control volume 502 around a building envelope 504 for the building 104.

In calculating the envelope efficiency, the control volume 502 is drawn around the building envelope 504 (the volume of the building 104) but excluding the HVAC system, as shown in FIG. 5. The energy consumed inside the building is included in the calculations. If the HVAC systems are included on the roof, the efficiency of the HVAC system becomes irrelevant in calculating the building's envelope efficiency. If HVAC systems are included within the building 104, then the heat generated by these systems has to be added to the building's internal heat load.

The energy balance equation for the control volume shown in FIG. 2 is given by:

ΔE_{building}=ΔQ_{conducted}+ΔQ_{transmitted}+ΔQ_{generated}+ΔQ_{transported}

where Q_{conducted} is the heat conducted through the walls, which is the sum of radiated and convected heat, Q_{transmitted} is the heat transmitted by light through windows and open surfaces, Q_{generated} is the heat generated inside the building, and Q_{transported} is the heat added or removed through mass transfer.

In the ideal case, the change of energy in a building is always zero and the heat removed from the building 104 is equal to the heat generated inside the building 104 plus the heat entering the building:

ΔQ_{transported}=ΔQ_{conducted}+ΔQ_{transmitted}+ΔQ_{generated}

In most cases, ΔQ_{transported} the heat (forcibly) transported to or from a building can be measured. The heat generated inside the building 104 can be calculated using actual measurements for heat generated by lighting systems and plug loads, and estimates for heat generated by occupants. The challenging part of the equation is the estimation of the heat entering or leaving through the walls.

If leaks through the building envelope 504 are ignored, then the ΔQ_{transported} is equal to the enthalpy difference of HVAC fluids entering and leaving the building. Hence, the more efficient the building envelope 504 is, the lower the amount of heat that has to be removed from within the building 104. Therefore the building envelope efficiency can be defined as:

$${η}_{envelope} = \frac{Δ {Q}_{{transported}_{min}}}{Δ {Q}_{{transported}_{actual}}}$$

$$where , Δ {Q}_{transported} = {( {H}_{air} + {H}_{water} )}_{out} - {( {H}_{air} + {H}_{water} )}_{in}$$

and can be measured in real time.

### Reference Case: Ideal Building in Hot Ambient Weather

The building 104 with optimum envelope efficiency, when subject to hot ambient weather and intense sun radiation, will have walls and windows with a thermal conductivity of zero, or a thermal insulation of infinity making ΔQ_{conducted}=0. The ideal building will have windows and open surfaces that can have 100% transmissivity when needed and 0% transmissivity when not needed. When ambient conditions are sunny and hot, the windows would have 0% transmissivity and all open surfaces will be closed, making ΔQ_{transmitted}=0.

Therefore, for the ideal building, the minimum value of ΔQ_{transported} is:

ΔQ_{transported}=ΔQ_{generated}

The efficiency of the control volume reduces to:

$$\begin{matrix}{η}_{envelope} = \frac{Δ {Q}_{{transported}_{min}}}{Δ {Q}_{{transported}_{actual}}} \\ = \frac{Δ {Q}_{generated}}{Δ {Q}_{{transported}_{actual}}} \\ = \frac{Δ {Q}_{generated}}{{( {H}_{air} + {H}_{water} )}_{out} - {( {H}_{air} + {H}_{water} )}_{in}}\end{matrix}$$

The closer the value of this metric is to 1, the closer the building 104 is to the ideal case of perfectly insulated walls and windows, i.e. a perfect envelope. The closer it is to 0, the farther it is from optimum envelope insulation.

This metric is a measure of the performance of the building envelope 504 but does not account for effects of ambient weather on the envelope efficiency. To illustrate this, consider the building 104 on two hot and sunny days. Assume that at both times, the building 104 has the same levels of ΔQ_{generated}. On the hotter day, ΔQ_{transported} actual will be larger to make up for the increase values of ΔQ_{transmitted} and ΔQ_{conducted} due to the higher ambient temperatures and solar irradiance. This will result in the building 104 seemingly having a lower envelope efficiency on the hotter day, even though the envelope is the same. The hotter the weather and the poorer the insulation, the closer this metric is to zero. This metric works well to compare buildings 104 that are subject to the same weather patterns. It will be proportional to the envelope efficiency of the respective buildings 104. The buildings 104 with better envelope efficiency will have a larger ratio. But if buildings 104 are in different climate zones, then a different metric is needed that takes into account real time ambient weather.

### Building Envelope Heat Removal Ratio

Consider the following ratio:

$$\begin{matrix}{Q}_{{ratio}_{actual}} = \frac{( actual heat removed )}{( absolute maximum heat that can enter the building )} \\ = \frac{{( {H}_{air} + {H}_{water} )}_{out} - {( {H}_{air} + {H}_{water} )}_{in}}{{Q}_{generated} + {Q}_{{transmitted}_{max}} + {Q}_{{conducted}_{max}}} \\ = \frac{{( {H}_{air} + {H}_{water} )}_{out} - {( {H}_{air} + {H}_{water} )}_{in}}{{Q}_{generated} + {Q}_{direct radiation} + {Q}_{reflected radiation} + {Q}_{diffuse radiation} + {Q}_{convected}}\end{matrix}$$

where the actual heat removed is the difference in enthalpy of the air conditioning fluids entering and leaving the building envelope 504 (downstream the HVAC systems). The absolute maximum heat that can enter the building 104 is the heat generated in the building 104 plus the heat that would enter the building 104 if the envelope had zero insulation, i.e. if all irradiated heat and convected heat entered the building instantly.

Effect of ambient weather: Increasing ambient temperature and solar irradiance will increase the absolute maximum heat that can possibly enter the building 104, and will also increase the amount of heat needed to be removed from the building 104 to maintain a constant internal temperature. Hence, the numerator and denominator in the equation above will both increase with increasing heat from the ambient weather.

Effect of increased internal load: Increasing heat generated by internal loads (lighting, plug load, occupants) will increase the maximum heat the building 104 is subjected to, and will also increase the amount of heat needed to be removed from the building 104 to maintain a constant internal temperature. Again, the numerator and denominator in the equation above will both increase with increasing heat from internal loads.

Effect of poor insulation: Poor insulation will lead to more heat entering the building envelope 504 and hence more heat that will have to be removed to maintain constant temperatures inside the building 104. In the ratio above, poorer insulation does not change the denominator since it assumes zero insulation, but only the numerator. Hence, everything else being equal, the poorer the insulation the more heat is removed from the building 104, the larger the value of the above ratio.

The above ratio is proportional to the insulation of the building envelope 504 and is used as a metric to measure the efficiency of the building envelope 504. The metric can be calculated in real time: the numerator is a value that is calculated knowing the supply and return temperatures of HVAC air and water, the denominator is a value that can be calculated knowing the location of the building, its orientation and the ambient weather conditions.

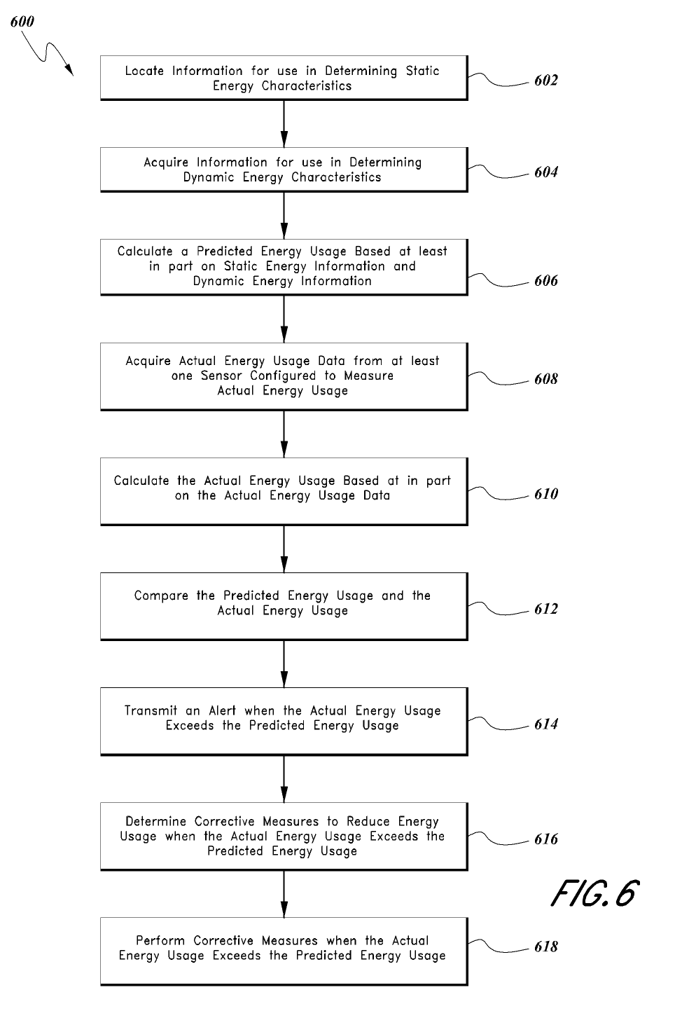

FIG. 6 is a flow chart of an exemplary process 600 of the energy management system 102 to reduce or optimize energy usage of the facility 104, including facility systems and facility subsystems. The facility 104 and/or building 104 refer to the facility, its systems and its subsystems in the following discussion. Beginning at block 602, the process 600 locates information for use in determining static energy characteristics of the facility 104. In an embodiment, the static energy characteristics of the facility 104 are energy related features of the facility 104 that do not change over time. Examples of the static energy data are square footage and number of floors, the properties of the wall insulation, the size and orientation of the windows, specification of the HVAC system, specification of the lighting system, list of integrated equipment and machinery, the efficiency of the HVAC system, the geographical orientation, facility BIM data, CAD drawings, panel schedules, electrical single line diagrams, and any other information relating to the design, construction, equipment, and material that does not change or changes rarely. In an embodiment, the static energy data are stored in the component/system/load libraries associated with the engineering design element 304.

At block 604, the process 600 acquires information for use in determining dynamic energy characteristics of the facility 104. In an embodiment, the dynamic energy characteristics of the facility 104 are energy related features of the facility 104 that change over time. Examples of dynamic energy data are occupancy schedule, usage schedule, ambient weather, weather forecast, utility rates, customer preferences, energy survey databases, utility meter data, third party software data, measure of building activity (production output, services performed, processes executed, patients processed, number of students, etc.), equipment duty cycles, maintenance logs, event logs, relevant alerts, and any other data relating to energy consumption of the facility that is time dependent or changes over time. In an embodiment, the dynamic energy data are stored in databases associated with the design management element 302, the engineering design element 304, the computer aided modeling element 306, the computer aided simulation element 308, the building construction management element 310, and the building commissioning management element 312.

At block 606, the process 600 calculates predicted energy usage of the facility 104 based at least in part on the static energy information and the dynamic energy information. In an embodiment, the continuous commissioning, verification, and optimization element 316 uses the static and dynamic energy data to calculate the predicted energy usage of the facility 104.

At block 608, the process 600 acquires actual energy usage data from at least one sensor configured to measure the actual energy usage of the facility 104. In an embodiment, the building management system embedded in the building commissioning management element 312 acquires information or sensor data from sensors and sensing modules installed in the building 104.

At block 610, the process 600 calculates the actual energy usage of the facility 104 based at least in part on the actual energy usage data. In an embodiment, the building commissioning management element 312 calculates the actual energy usage. In another embodiment, the continuous commissioning, verification and optimization element 316 calculates the actual energy usage of the facility 104.

At block 612, the process 600 compares the predicted or estimated energy usage of the facility 104 with the actual energy usage of the facility 104. In an embodiment, the process 600 calculates one or more of the building energy efficiency, the HVAC energy efficiency, the lighting energy efficiency, the plug load energy efficiency, and the building envelope efficiency.

At block 614, the process 600 transmits an alert when the actual energy usage of the facility 104 or any of its subsystems exceeds the predicted energy usage of the facility 104 or the respective subsystem by a user determined amount. In an embodiment, the alert is transmitted when the actual energy usage exceeds the predicted energy usage by at least 10%. In another embodiment, the alert is transmitted when the actual energy usage exceeds the predicted energy usage by at least 2% or any other amount selected or determined by the user. In another embodiment, the process 600 transmits an alert when one or more of the building energy efficiency, the HVAC energy efficiency, the lighting energy efficiency, the plug load energy efficiency, and the building envelope efficiency does not exceed a user specified ratio. In yet another embodiment, the alert is transmitted by one of the building commissioning management element 312, the building energy management and control element 314, and the continuous commissioning, verification and optimization element 316.

In another embodiment, at block 614, when actual energy exceeds predicted energy usage, the process 600 can identify malfunctioning equipment based on their energy consumption and measured performance. For example, where the process measures pressure upstream and downstream for a pump associated with the facility. Based at least in part on its energy consumption, the process 600 determines that the pump is malfunctioning. Hence the process 600 transmits prioritized alerts of malfunctioning systems associated with the facility 104.

At block 616, the process 600 determines corrective measures to reduce energy usage of the facility 104 when the when the actual energy usage of the facility 104 exceeds the predicted energy usage of the facility 104 by the user determined amount. In an embodiment, the corrective measures are determined when the actual energy usage exceeds the predicted energy usage by at least 10%. In another embodiment, the corrective measures are determined when the actual energy usage exceeds the predicted energy usage by at least 2%. In another embodiment, the corrective measures are determined by one of the building commissioning management element 312, the building energy management and control element 314, and the continuous commissioning, verification and optimization element 316.

At block 618, the process 600 performs corrective measures to reduce the energy usage of the facility when the actual energy usage of the facility 104 exceeds the predicted energy usage of the facility 104 by a user determined amount. In an embodiment, the corrective measures are performed when the actual energy usage exceeds the predicted energy usage by at least 10%. In another embodiment, the corrective measures are performed when the actual energy usage exceeds the predicted energy usage by at least 2%. In another embodiment, the corrective measures are performed by one of the building commissioning management element 312, the building energy management and control element 314, and the continuous commissioning, verification and optimization element 316, which transmits control signals through the network 110 to the facility 104.

Depending on the embodiment, certain acts, events, or functions of any of the algorithms described herein can be performed in a different sequence, can be added, merged, or left out altogether (e.g., not all described acts or events are necessary for the practice of the algorithm). Moreover, in certain embodiments, acts or events can be performed concurrently, e.g., through multi-threaded processing, interrupt processing, or multiple processors or processor cores or on other parallel architectures, rather than sequentially.

The various illustrative logical blocks, modules, and algorithm steps described in connection with the embodiments disclosed herein can be implemented as electronic hardware, computer software, or combinations of both. To clearly illustrate this interchangeability of hardware and software, various illustrative components, blocks, modules, and steps have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described in connection with the embodiments disclosed herein can be implemented or performed by a machine, such as a general purpose processor, a digital signal processor (DSP), an ASIC, a FPGA or other programmable logic device, discrete gate or transistor logic, discrete hardware components, or any combination thereof designed to perform the functions described herein. A general purpose processor can be a microprocessor, but in the alternative, the processor can be a controller, microcontroller, or state machine, combinations of the same, or the like. A processor can also be implemented as a combination of computing devices, e.g., a combination of a DSP and a microprocessor, a plurality of microprocessors, one or more microprocessors in conjunction with a DSP core, or any other such configuration.

The steps of a method, process, or algorithm described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of computer-readable storage medium known in the art. An exemplary storage medium can be coupled to the processor such that the processor can read information from, and write information to, the storage medium. In the alternative, the storage medium can be integral to the processor. The processor and the storage medium can reside in an ASIC.

The above detailed description of certain embodiments is not intended to be exhaustive or to limit the invention to the precise form disclosed above. While specific embodiments of, and examples for, the invention are described above for illustrative purposes, various equivalent modifications are possible within the scope of the invention, as those ordinary skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The words “coupled” or connected”, as generally used herein, refer to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The teachings of the invention provided herein can be applied to other systems, not necessarily the systems described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method to manage energy usage, the method comprising:
electronically receiving with computer hardware static energy data associated with a facility, wherein the static energy data comprises time-independent information;
electronically receiving with the computer hardware dynamic energy survey data from at least one occupant of the facility, wherein the energy survey data comprises time-dependent information;
electronically receiving with the computer hardware sensor data from at least one sensor configured to measure the energy usage of the facility; and
calculating with the computer hardware energy assessment data and energy guidance data for the facility based at least in part on the static energy data, the dynamic energy survey data, and the sensor data.

2. The method of claim 1 wherein the at least one occupant transmits the dynamic energy survey data using a mobile based application of a mobile communication device.

3. The method of claim 1 further comprising electronically surveying the at least one occupant using at least one of desktop, mobile, and web based applications.

4. The method of claim 1 wherein the dynamic energy survey data comprises data indicating a comfort level of the at least one occupant.

5. The method of claim 1 further comprising soliciting electronic feedback from the at least one occupant using at least one of desktop, mobile, and web based applications.

6. The method of claim 1 further comprising accepting electronic problem reporting from the at least one occupant using at least one of desktop, mobile, and web based applications.

7. The method of claim 1 wherein electronically receiving the static energy data, electronically receiving the dynamic energy survey data, electronically receiving the sensor data, and calculating are electronically performed through the Internet and wherein commands to control subsystems of the facility are electronically communicated to the facility through the Internet.

8. The method of claim 1 wherein the method is performed under control of a cloud computing environment including one or more servers and one or more data storage.

9. A method to manage energy usage, the method comprising:
electronically receiving with computer hardware static energy data associated with a facility, wherein the static energy data comprises time-independent information;
electronically receiving with the computer hardware dynamic energy survey data from at least one occupant of the facility, wherein the energy survey data comprises time-dependent information;
electronically receiving with the computer hardware sensor data from at least one sensor configured to measure the energy usage of the facility; and
controlling with the computer hardware subsystems associated with the energy usage of the facility based at least in part on the static energy data, the dynamic energy survey data, and the sensor data.

10. The method of claim 9 wherein the at least one occupant transmits the dynamic energy survey data using a mobile based application of a mobile communication device.

11. The method of claim 9 further comprising electronically surveying the at least one occupant using at least one of desktop, mobile, and web based applications.

12. The method of claim 9 wherein the dynamic energy survey data comprises data indicating a comfort level of the at least one occupant.

13. The method of claim 9 further comprising soliciting electronic feedback from the at least one occupant using at least one of desktop, mobile, and web based applications.

14. The method of claim 9 further comprising accepting electronic problem reporting from the at least one occupant using at least one of desktop, mobile, and web based applications.

15. An energy management system to manage energy usage of a facility, the system comprising:
a building energy management and control element comprising computer hardware and configured to electronically receive static energy data associated with a facility, wherein the static energy data comprises time-independent information;
the building energy management and control element further configured to electronically receive dynamic energy survey data from at least one occupant of the facility, wherein the energy survey data comprises time-dependent information;
the building energy management and control element further configured to electronically receive sensor data from at least one sensor configured to measure the energy usage of the facility; and
the building energy management and control element further configured to calculate energy assessment data and energy guidance data for the facility based at least in part on the static energy data, the dynamic energy survey data, and the sensor data.

16. The energy management system of claim 15 wherein the at least one occupant transmits the dynamic energy survey data using a mobile based application of a mobile communication device.

17. The energy management system of claim 15 wherein the building energy management and control element is further configured to electronically survey the at least one occupant using at least one of desktop, mobile, and web based applications.

18. The energy management system of claim 15 wherein the dynamic energy survey data comprises data indicating a comfort level of the at least one occupant.

19. The energy management system of claim 15 wherein the building energy management and control element is further configured to solicit electronic feedback from the at least one occupant using at least one of desktop, mobile, and web based applications.

20. The energy management system of claim 15 wherein the building energy management and control element is further configured to accept electronic problem reporting from the at least one occupant using at least one of desktop, mobile, and web based applications.
